(19) United States
(12) Patent Application Publication
(10) Pub. No.: US 2021/0139070 A1
(43) Pub. Date: May 13, 2021

(54) ELECTRIC DRIVING DEVICE AND ELECTRIC POWER STEERING DEVICE

(71) Applicant: HITACHI AUTOMOTIVE SYSTEMS, LTD., Hitachinaka-shi, Ibaraki (JP)

(72) Inventors: Tetsuro TATEYAMA, Hitachinaka-shi, Ibaraki (JP); Kazuhiko NAKANO, Hitachinaka-shi, Ibaraki (JP); Haruaki MOTODA, Hitachinaka-shi, Ibaraki (JP)

(73) Assignee: HITACHI AUTOMOTIVE SYSTEMS, LTD., Hitachinaka-shi, Ibaraki (JP)

(21) Appl. No.: 16/620,781

(22) PCT Filed: May 11, 2018
(86) PCT No.: PCT/JP2018/018240

§ 371 Date: Dec. 9, 2019

(30) Foreign Application Priority Data
Jun. 16, 2017 (JP) 2017-118629

(51) Int. Cl. B62D 5/04; H02K 11/33; H02K 5/22; H05K 7/20

(52) U.S. Cl. CPC B62D 5/0406; H02K 11/33; B62D 5/046; H05K 7/20436; H02K 5/22

(57) ABSTRACT

A plurality of circuit boards (31), (34) are stacked at a side end wall (15), located an opposite side to an output shaft portion (14) of rotation shaft of electric motor, of a motor housing (11). Besides a circuit board fixing portion (26) for the one circuit board (34), heat-releasing member (38) that thermally connects one surface of the circuit board (34) and a metal cover (12) covering the circuit board (34) is provided between the one surface of the circuit board (34) and the metal cover (12). Besides connecting the circuit board (34) to the circuit board fixing portion (26), by thermally connecting the one surface of the circuit board (34) and the metal cover (12) through the heat-releasing member (38), it is possible to adequately release heat generated from a transistor, then influence of heat on electronic circuit element that is susceptible to heat can be suppressed.

### TECHNICAL FIELD

The present invention relates to an electric driving device and an electric power steering device, and more particularly to an electric driving device and an electric power steering device in which an electronic control device is mounted.

### BACKGROUND ART

In a field of general industrial equipment, a mechanical control element is driven by an electric motor. In recent years, so-called electrically mechanically integrated electric driving device, which is configured such that an electronic control unit formed from a semiconductor element etc. controlling a rotation speed and/or a rotation torque of the electric motor is integrally mounted in the electric motor, has been used.

As an example of the electrically mechanically integrated electric driving device, for instance, an electric power steering device is configured such that a turning direction and a turning torque of a steering shaft that turns by driver's operation of a steering wheel are detected, and on the basis of these detection values, the electric motor is driven so as to rotate in the same direction as the turning direction of the steering shaft, then a steering assist torque is generated. To control this electric motor, the power steering device is provided with an electronic control unit (ECU: Electronic Control Unit).

As a related art electric power steering device, for instance, an electric power steering device disclosed in Japanese Unexamined Patent Application Publication No. 2016-036246 (Patent Document 1) is known. Patent Document 1 discloses the electric power steering device configured by an electric motor unit and an electronic control unit. An electric motor of the electric motor unit is housed in a motor housing having a cylindrical portion made of aluminum alloy etc. . . . A board of the electronic control unit an which electronic elements or components are mounted is fixed to a heat sink member that is located at an opposite side to an output shaft of the electric motor in an axial direction of the motor housing and serves as a lid of the motor housing.

The board fixed to the heat sink member mounts thereon a power supply circuit unit, a power conversion circuit unit (a power module) having a power switching element such as a MOSFET and an IGBT that drive and control the electric motor, and a control circuit unit that controls the power switching element. An output terminal of the power switching element and an input terminal of the electric motor are electrically connected through a bus bar.

Power is supplied to the electronic control unit fixed to the heat sink member from a power supply through a connector case made of synthetic resin. Further, detection signals concerning an operating state etc. are sent to the electronic control unit from detection sensors. The connector case functions as a lid member or a cover member, and is fixed to an outer peripheral surface of the heat sink member with a fixing screw so as to hermetically seal the heat sink member.

In the electric power steering device having such configuration as disclosed in Patent Document 1, the control circuit unit, the power supply circuit unit and the power conversion circuit unit are mounted on the one circuit board. And, in order to radiate or release heat from this circuit board to the outside, the circuit board is fixed to the heat sink member serving as the lid member of the motor housing.

As another electric driving device in which the electronic control device is integrally mounted, an electric brake and an electric hydraulic pressure controller for various kinds of hydraulic pressure control are known. In the following description, the electric power steering device from among these electric driving devices will be explained.

### CITATION LIST

### Patent Document

Patent Document 1 Japanese Unexamined Patent Application Publication No. 2016-036246

### SUMMARY OF THE INVENTION

### Technical Problem

This kind of electric power steering device is placed in an engine room of the vehicle. Therefore, size reduction in configuration of the electric power steering device is required. In particular, there has been a tendency in recent years for various auxiliary devices such as an exhaust gas control device and a safety precaution device to be disposed in the engine room of the vehicle. It is therefore required for the auxiliary devices including the electric power steering device to be as small as possible. Particularly, size reduction in a radial direction is required.

Further, in addition to the size reduction, it is also required to provide a redundant system (a dual-redundancy system) for the electronic control unit. However, if electronic control units forming the redundant system are mounted on the one circuit board, there arises a problem of increasing a size of the circuit board in the radial direction.

To resolve this problem, if two or more circuit boards (a plurality of circuit boards), each of which mounts thereon necessary electronic control circuits, are arranged so as to be stacked in the axial direction of the motor housing, a shape in the radial direction of the electronic control unit can be small, and this would be an effective manner.

Here, if the plurality of circuit boards are arranged so as to be stacked, heat from one circuit board can be released well by fixing this circuit board to the heat sink member serving as the lid member as disclosed in Patent Document 1. However, radiation or release of heat from the other circuit board is limited to a radiation route (a heat release route) such as a mount fixing portion of the circuit board. As an electronic circuit element that generates heat among electronic circuit elements mounted on the circuit board, it is mainly a transistor, e.g. a bipolar transistor.

This transistor withstands a relatively high temperature. However, the electronic circuit element other than this transistor, for example, an electronic circuit element like a ceramic capacitor, is affected by temperature. Therefore, since the release of heat from the other circuit board is limited to the heat release route such as the mount fixing portion of the circuit board, heat generated from the transistor cannot be adequately released. Because of this, measures for releasing heat of the electronic circuit element that is susceptible to heat are required.

An object of the present invention is therefore to provide an electric driving device and an electric power steering device each having a new configuration that is capable of adequately releasing heat of the stack-arranged circuit boards.

### Solution to Problem

An electric driving device comprises: a motor housing accommodating therein an electric motor that drives a mechanical control element; an electronic control unit provided at a side end wall side of the motor housing which is an opposite side to an output shaft portion of a rotation shaft of the electric motor and configured to drive the electric motor; and a metal cover fixed to the side end wall of the motor housing and covering the electronic control unit. And, the electronic control unit is configured by a plurality of stacked circuit boards. Further, besides a mount fixing portion for at least one circuit board, a heat-releasing member that thermally connects one surface of the one circuit board and the metal cover is provided between the one surface of the one circuit board and the metal cover.

### Effects of Invention

According to the present invention, besides connecting the one circuit board to the mount fixing portion formed at the side end wall of the motor housing, the one surface of the one circuit board and the metal cover are thermally connected through the heat-releasing member. It is therefore possible to adequately release heat generated from a transistor, then an influence of heat on an electronic circuit element that is susceptible to heat can be suppressed.

### BRIEF DESCRIPTION OF THE DRAWINGS

FIG. 1 is a general perspective view of a steering device as an example to which the present invention is applied.

FIG. 2 is a general perspective view of an electric power steering device according to an embodiment of the present invention.

FIG. 3 is a perspective exploded view of the electric power steering device shown in FIG. 2.

FIG. 4 is a perspective view of a motor housing shown in FIG. 3.

FIG. 5 is a cross section of the motor housing shown in FIG. 4, which is cut in an axial direction of the motor housing.

FIG. 6 is a perspective view of the motor housing shown in FIG. 4 with a power conversion circuit unit mounted on the motor housing.

FIG. 7 is a perspective view of the motor housing shown in FIG. 4 with a power supply circuit unit further mounted on the motor housing.

FIG. 8 is a perspective view of the motor housing shown in FIG. 4 with a control circuit unit further mounted on the motor housing.

FIG. 9 is a perspective view of the motor housing shown in FIG. 4 and a metal cover that is going to be fixed to the motor housing.

FIG. 10 is a cross section around a connector terminal assembly for explaining a heat release structure of the metal cover and a circuit board.

### EMBODIMENTS FOR CARRYING OUT THE INVENTION

An embodiment of the present invention will be explained in detail below with reference to the drawings. The present invention is not limited to the following embodiment, and includes all design modifications and equivalents belonging to the technical scope of the present invention.

Before explaining the embodiment of the present invention, a configuration of a steering device as an example to which the present invention is applied will be briefly explained using FIG. 1.

First, a steering device to steer front wheels of a vehicle will be explained. A steering device 1 is configured as shown in FIG. 1. A pinion (not shown) is provided at a lower end of a steering shaft 2 connecting to a steering wheel (not shown). This pinion is engaged with a rack (not shown) that extends in right and left directions of a vehicle body. A tie rod 3 to steer the front wheels in the right and left directions is each connected to both ends of the rack. The rack is accommodated in a rack housing 4. Between the rack housing 4 and each tie rod 3, a rubber boot 5 is provided.

The steering device 1 is provided with an electric power steering device 6 to assist torque when performing a turning operation of the steering wheel. That is, a torque sensor 7 that detects a turning direction and a turning torque of the steering shaft 2 is provided. And, an electric motor unit 8 that provides a steering assistive force to the rack via a gear 10 on the basis of a detection value of the torque sensor 7 is provided. Further, an electronic control unit (ECU) 9 that controls an electric motor disposed in the electric motor unit 8 is provided. The electric motor unit 8 of the electric power steering device 6 is connected to the gear 10 at three portions of an outer periphery at an output shaft side of the electric motor unit 8 with bolts (not shown). The electronic control unit 9 is disposed on an opposite side to the output shaft side of the electric motor unit 8.

In the electric power steering device 6, when the steering shaft 2 is turned in any turning direction by the steering wheel operation, the torque sensor 7 detects the turning direction and the turning torque of the steering shaft 2. A control circuit unit calculates a drive operation amount of the electric motor on the basis of these detection values. The electric motor is then driven by a power switching element of a power conversion circuit unit on the basis of the calculated drive operation amount. And, an output shaft of the electric motor rotates so as to drive and rotate the steering shaft 2 in the same direction as a direction of the steering wheel operation. This rotation of the output shaft of the electric motor is transmitted to the rack (not shown) through the pinion (not shown) and the gear 10, and the vehicle is steered. Since such configuration and workings are well known, a further explanation will be omitted here.

Here, as mentioned above, if the plurality of circuit boards are arranged so as to be stacked, heat from one circuit board can be released well by fixing this circuit board to the heat sink member serving as the lid member as disclosed in Patent Document 1. However, radiation or release of heat from the other circuit board is limited to the radiation route (the heat release route) such as the mount fixing portion of the circuit board. As an electronic circuit element that generates heat among electronic circuit elements mounted on the circuit board, it is mainly a transistor, e.g. a bipolar transistor.

Although this transistor withstands a relatively high temperature, the electronic circuit element other than this transistor, for example, an electronic circuit element like a ceramic capacitor, is affected by temperature. Therefore, since the release of heat from the other circuit board is limited to the heat release route such as the mount fixing portion of the circuit board, heat generated from the transistor cannot be adequately released. Because of this, measures for releasing heat of the electronic circuit element that is susceptible to heat are required.

From such background, the present embodiment proposes the electric power steering device having the following configuration. That is, in the present embodiment, a plurality of circuit boards are stacked at a side end wall, located an opposite side to an output shaft portion of a rotation shaft of an electric motor, of a motor housing. And, besides a mount fixing portion for at least one circuit board, a heat-releasing member that thermally connects one surface of the circuit board and a metal cover covering the circuit board is provided between the one surface of the circuit board and the metal cover.

According to this configuration, by thermally connecting the one surface of the circuit board to the metal cover through the heat-releasing member besides connecting the circuit board to the mount fixing portion, it is possible to adequately release heat generated from the transistor, then an influence of heat on the electronic circuit element that is susceptible to heat can be suppressed.

In the following description, a configuration of the electric power steering device according to the embodiment of the present invention will be explained in detail with reference to FIGS. 2 to 10. FIG. 2 is a drawing showing a general configuration of the electric power steering device according to the present embodiment. FIG. 3 is a drawing, viewed from an oblique direction, with components of the electric power steering device shown in FIG. 2 dismantled. FIGS. 4 to 9 are drawings showing assembly states of components that are assembled in an assembly order. FIG. 10 is a drawing for explaining a specific configuration of a heat release structure. The embodiment will be explained below with reference to the drawings.

As shown in FIG. 2, an electric motor unit 8 forming the electric power steering device is configured by a motor housing 11 having a cylindrical portion made of aluminum alloy etc. and an electric motor (not shown) accommodated in the motor housing 11. An electronic control unit 9 is configured by a metal cover 12 made of aluminum alloy etc. and located at an opposite side to an output shaft of the electric motor in an axial direction of the motor housing 11 and an electronic control unit (not shown) accommodated in this metal cover 12.

The motor housing 11 and the metal cover 12 are fixedly connected to each other at their opposing end surfaces with an adhesive or fixing bolts or by welding. The electronic control unit accommodated in an inside accommodation space of the metal cover 12 is configured by a power supply circuit unit that generates a required power, a power conversion circuit unit having a power switching element such as a MOSFET and an IGBT that drive and control the electric motor of the electric motor unit 8, and a control circuit unit that controls the power switching element. An output terminal of the power switching element and an input terminal of a coil of the electric motor are electrically connected through a bus bar.

A connector terminal assembly 13 is fixed to an end surface of the metal cover 12 with fixing bolts. The connector terminal assembly 13 has a connector terminal forming portion 13A for power supply, a connector terminal forming portion 13B for detection sensors, and a connector terminal forming portion 13C for control state output by which a control state is outputted to an external device. The electronic control unit accommodated in the metal cover 12 is supplied with power from a power supply through the synthetic-resin-made connector terminal forming portion 13A for power supply. Further, the electronic control unit is provided with detection signals of an operating condition etc. from the detection sensors through the connector terminal forming portion 13B for detection sensors. A current control state signal of the electric power steering device is outputted from the electronic control unit through the connector terminal forming portion 13C for control state output.

FIG. 3 is a perspective exploded view of the electric power steering device 6. An iron-made annular side yoke (not shown) is fitted to an inside of a motor housing 11. The electric motor is accommodated inside this side yoke. An output shaft portion 14 of the electric motor provides the steering assistive force to the rack via the gear. Since a specific structure of the electric motor is well known, its explanation will be omitted here.

The motor housing 11 is made of aluminum alloy, and acts as a heat sink that radiates or releases heat generated at the electric motor and heat generated in after-mentioned power supply circuit unit and power conversion circuit unit to the outside atmosphere. The electric motor and the motor housing 11 form the electric motor unit 8.

The electronic control unit EC is connected to a side end wall 15 of the motor housing 11 which is an opposite side to the output shaft portion 14 of the electric motor unit 8. The electronic control unit EC has the power conversion circuit unit 16, the power supply circuit unit 17 and the control circuit unit 18. The side end wall 15 of the motor housing 11 is formed integrally with the motor housing 11. However, the side end wall 15 could be formed separately from the motor housing 11, then fixed to the motor housing 11 with bolts or by welding.

Here, the power conversion circuit unit 16, the power supply circuit unit 17 and the control circuit unit 18 form a redundant system (a dual-redundancy system) by a main electronic control unit and a sub-electronic control unit. In a normal condition, the electric motor is driven and controlled by the main electronic control unit. However, if an abnormal condition or a failure occurs at the main electronic control unit, the control is switched to the sub-electronic control unit, and the electric motor is driven and controlled by the sub-electronic control unit.

Therefore, normally, heat from the main electronic control unit is transmitted to the motor housing 11. If the abnormal condition or the failure occurs at the main electronic control unit, the main electronic control unit stops and the sub-electronic control unit operates, then heat from the sub-electronic control unit is transmitted to the motor housing 11. These will be described later.

However, both of the main electronic control unit and the sub-electronic control unit could operate as a regular electronic control unit, although the present invention does not apply this configuration. And, if the abnormal condition or the failure occurs at one of the electronic control units, the other electronic control unit drives and controls the electric motor by half ability. In this case, although capability of the electric motor is half, so-called limp-home function is secured. Therefore, in the normal condition, heat from the main electronic control unit and the sub-electronic control unit is transmitted to the motor housing 11. It is noted that even if no redundant system is employed, the present embodiment can be realized.

The electronic control unit EC is configured by the power conversion circuit unit 16, the power supply circuit unit 17, the control circuit unit 18 and the connector terminal assembly 13. These power conversion circuit unit 16, power supply circuit unit 17, control circuit unit 18 and connector terminal assembly 13 are arranged in this order from the side end wall 15 side to a direction moving away from the side end wall 15. The control circuit unit 18 is a unit that generates a control signal for driving the switching element of the power conversion circuit unit 16, and is configured by a microcomputer and a peripheral circuit and so on. The power supply circuit unit 17 is a unit that generates power to drive the control circuit unit 18 and power for the power conversion circuit unit 16, and is configured by a capacitor, a coil and a switching element and so on. The power conversion circuit unit 16 is a unit that controls power (current) flowing in the coil of the electric motor, and is configured by a switching element that forms three-phase upper and lower arms and so on.

A unit having a large heat value in the electronic control unit EC is mainly the power conversion circuit unit 16 and the power supply circuit unit 17. Heat of the power conversion circuit unit 16 and the power supply circuit unit 17 is released from the motor housing 11 made of aluminum alloy. Between the control circuit unit 18 and the metal cover 12, cylindrical column-shaped heat-radiating members (heat-releasing members or heat-transmitting members) 38 are provided. The heat-releasing member 38 thermally connects the control circuit unit 18 and the metal cover 12 through an insertion hole 39 that is formed at the connector terminal assembly 13. Heat of the control circuit unit 18 is then released from the metal cover 12. These will be described later.

The synthetic-resin-made connector terminal assembly 13 is arranged between the control circuit unit 18 and the metal cover 12, and is connected to a vehicle battery (the power supply) and other external control device (not shown) to which the current control state of the electric power steering device is outputted. Needless to say, the connector terminal assembly 13 is connected to the power conversion circuit unit 16, the power supply circuit unit 17 and the control circuit unit 18.

The metal cover 12 has a function of accommodating and liquid-tightly sealing the power conversion circuit unit 16, the power supply circuit unit 17 and the control circuit unit 18. In the present embodiment, the metal cover 12 is fixed to the motor housing 11 by welding. Since the metal cover 12 is made of metal, the metal cover 12 also has a function of radiating or releasing heat generated at the power conversion circuit unit 16 and the power supply circuit unit 17 etc. to the outside.

Next, structure or configuration of each component and an assembling method of the components will be explained with reference to FIGS. 4 to 9. FIG. 4 is an external view of the motor housing 11. FIG. 5 is a cross section of the motor housing 11, which is cut in an axial direction of the motor housing 11.

In FIGS. 4 and 5, the motor housing 11 is shaped into a cylindrical or tubular shape. The motor housing 11 has a side peripheral surface portion 11A, the side end wall 15 that closes one end of the side peripheral surface portion 11A and a side end wall 19 that closes the other end of the side peripheral surface portion 11A. In the present embodiment, the side peripheral surface portion 11A and the side end wall 15 are formed integrally with each other, then the motor housing 11 has a bottomed cylindrical shape. The side end wall 19 serves as a lid, and closes the other end of the side peripheral surface portion 11A after accommodating the electric motor in the side peripheral surface portion 11A.

As shown in FIG. 5, a stator 21 having cores around which coils 20 are wound is fitted in the side peripheral surface portion 11A, and a rotor 22 in which a permanent magnet is embedded is rotatably accommodated inside this stator 21. A rotation shaft 23 is fixed to the rotor 22, and its one end is the output shaft portion 14, and its other end is a rotation detection portion 24 for detecting a rotation phase and a rotation speed of the rotation shaft 23. The rotation detection portion 24 is provided with a permanent magnet, and protrudes to the outside through a penetration hole 25 formed at the side end wall 15. The rotation phase and the rotation speed of the rotation shaft 23 are detected by a magnetism detecting portion configured by a GMR element (not shown) etc . . . .

Returning to FIG. 4, heat radiating sections (heat releasing sections) 15A and 15B for the power conversion circuit unit 16 and the power supply circuit unit 17 are formed on a surface of the side end wall 15 located at an opposite side to the output shaft portion 14 of the rotation shaft 23. Further, the circuit board fixing portions 26 as mount fixing portions of the circuit board are formed integrally with the side end wall 15 at four corners of the side end wall 15 so as to stand on or protrude from the surface of the side end wall 15. Each circuit board fixing portion 26 has a screw hole inside the circuit board fixing portion 26. The circuit board fixing portion 26 is provided to secure an after-mentioned glass epoxy circuit board 34 of the control circuit unit 18, and has a function of releasing (or transmitting) heat of the circuit board of the control circuit unit 18 to the motor housing 11.

The circuit board fixing portions 26 protruding from the power-conversion-circuit heat releasing section 15A (described later) each have a circuit board receiving portion 27 whose height in the axial direction is the same as that of the power-supply-circuit heat releasing section 15B (described later). This circuit board receiving portion 27 is a portion on which an after-mentioned glass epoxy circuit board 31 of the power supply circuit unit 17 is mounted. As can be seen from FIG. 4, a plane area forming the side end wall 15, which is orthogonal to the rotation shaft 23, is sectioned off into two sections. One is the power-conversion-circuit heat releasing section 15A to which the power conversion circuit unit 16 is fixed, and the other is the power-supply-circuit heat releasing section 15B to which the power supply circuit unit 17 is fixed. In the present embodiment, an area of the power-conversion-circuit heat releasing section 15A is greater than that of the power-supply-circuit heat releasing section 153. This is because that the redundant system is employed as described above and a mounting area of the power conversion circuit unit 16 is secured.

And, a different height step in the axial direction (a direction in which the rotation shaft 23 extends) is provided between the power-conversion-circuit heat releasing section ISA and the power-supply-circuit heat releasing section 15B. That is, the power-supply-circuit heat releasing section 15B is formed so as to have a step that is away from the power-conversion-circuit heat releasing section 15A in the direction of the rotation shaft 23 of the electric motor. This step is set to such a height that the power conversion circuit unit 16 and the power supply circuit unit 17 do not interfere with each other when the power supply circuit unit 17 is mounted after the power conversion circuit unit 16 is mounted.

The power-conversion-circuit heat releasing section 15A is provided with three long narrow rectangular protruding heat releasing portions 28. These protruding heat releasing portions 28 are portions on which the power conversion circuit unit 16 for the redundant system is mounted. The protruding heat releasing portions 28 protrude from the surface of the power-conversion-circuit heat releasing section 15A in the direction of the rotation shaft 23 of the electric motor so as to be away from the electric motor.

The power-supply-circuit heat releasing section 15B is formed into a flat surface, and the power supply circuit unit 17 is mounted on the power-supply-circuit heat releasing section 15B. Therefore, the protruding heat releasing portion 28 acts as a heat releasing portion that releases and transmits heat generated at the power conversion circuit unit 16 to the side end wall 15, and the power-supply-circuit heat releasing section 15B acts as a heat releasing portion that releases and transmits heat generated at the power supply circuit unit 17 to the side end wall 15. The protruding heat releasing portions 28 might be removed. In this case, the power-conversion-circuit heat releasing section 15A acts as the heat releasing portion that releases and transmits heat generated at the power conversion circuit unit 16 to the side end wall 15.

As described above, in the present embodiment, since the side end wall 15 of the motor housing 11 acts as a heat sink member, a separately-formed heat sink member is not needed, then a length in the axial direction can be shortened. Further, since the motor housing 11 has a sufficient heat capacity, it is possible to efficiently radiate or release heat of the power supply circuit unit 17 and the power conversion circuit unit 16 to the outside from the motor housing 11.

Next, FIG. 6 shows a state in which the power conversion circuit unit 16 is mounted on the protruding heat releasing portions 28. As shown in FIG. 6, the power conversion circuit unit 16 forming the redundant system is mounted on the protruding heat releasing portions 28 formed on the power-conversion-circuit heat releasing section 15A. The power conversion circuit unit 16 is configured by a main power conversion circuit unit 16M, a sub-power conversion circuit unit 16S and an abnormality response circuit unit 16E. The switching element forming the power conversion circuit unit 16 is mounted on a metal board (using an aluminum-based metal), which is a good heat radiation configuration. The switching element including the metal board at the switching element side is packaged with synthetic resin.

Thus, the metal board of the power conversion circuit unit 16 is thermally connected to the protruding heat releasing portion 28. With this configuration, heat generated at the switching element can be efficiently transmitted to the protruding heat releasing portion 28. A heat transfer grease (or a thermal conductive grease) is applied between the metal board of the power conversion circuit unit 16 and the protruding heat releasing portion 28, which facilitates heat transmission from the power conversion circuit unit 16 to the protruding heat releasing portion 28. Further, the power conversion circuit unit 16 is pressed and held toward the protruding heat releasing portion 28 side by an elastic function member of a power conversion circuit unit fixing member which is attached to an end portion of the rotation shaft 23.

Heat transmitted to the protruding heat releasing portion 28 diffuses through the power-conversion-circuit heat releasing section 15A, and is further transmitted to the side peripheral surface portion 11A of the motor housing 11, then is released to the outside. Here, as mentioned above, since a height of the power-conversion-circuit heat releasing section 15A in the axial direction is lower than that of the power-supply-circuit heat releasing section 15B, the power conversion circuit unit 16 does not interfere with the power supply circuit unit 17.

Next, FIG. 7 shows a state in which the power supply circuit unit 17 is mounted above or over the power conversion circuit unit 16. As shown in FIG. 7, the power supply circuit unit 17 is mounted on the power-supply-circuit heat releasing section 15B. Capacitors 29 and coils 30 and so on which form the power supply circuit unit 17 are mounted on the glass epoxy circuit board 31. The power supply circuit unit 17 has the redundant system, and as can be seen from the drawings, power supply circuits configured by the capacitors 29 and the coils 30 etc., which are arranged symmetrically with respect to each other, are provided.

A surface at the power-supply-circuit heat releasing section 15B side of this glass epoxy circuit board 31 is fixed to the side end wall 15 so as to contact the power-supply-circuit heat releasing section 15B. As a fixing manner, as shown in FIG. 7, the glass epoxy circuit board 31 is fixed to the screw holes provided at the circuit board receiving portions 27 of the circuit board fixing portions 26 with fixing bolts (not shown), and also fixed to the screw holes provided at the power-supply-circuit heat releasing section 15B with fixing bolts (not shown).

Here, since the power supply circuit unit 17 is formed by the glass epoxy circuit board 31, the circuit units could be mounted on both sides of the glass epoxy circuit board 31. On the surface at the power-supply-circuit heat releasing section 15B side of the glass epoxy circuit board 31, the GMR element (not shown) or a rotation phase and rotation speed detection unit that is configured by a detection circuit formed by the GMR element is mounted, and detects the rotation phase and the rotation speed of the rotation shaft 23 in cooperation with the rotation detection portion 24 provided at the rotation shaft 23.

As described above, since the glass epoxy circuit board 31 is fixed to the side end wall 15 so as to contact the power-supply-circuit heat releasing section 15B, it is possible to efficiently transmit heat generated at the power supply circuit unit 17 to the power-supply-circuit heat releasing section 15B. Heat transmitted to the power-supply-circuit heat releasing section 15B is further transmitted to and diffuses through the side peripheral surface portion 11A of the motor housing 11, then is released to the outside. Here, by interposing one of a good heat transfer adhesive (or a good thermal conductive adhesive), a heat transfer grease (or a thermal conductive grease) and a heat transfer sheet (or a thermal conductive sheet) between the glass epoxy circuit board 31 and the power-supply-circuit heat releasing section 155, a heat transfer performance (or a thermal conductivity) can be further improved.

Next, FIG. 8 shows a state in which the control circuit unit 18 is mounted above or over the power supply circuit unit 17. As shown in FIG. 8, the control circuit unit 18 is mounted above or over the power supply circuit unit 17. Microcomputers 32 and peripheral circuits 33 which form the control circuit unit 18 are mounted on the glass epoxy circuit board 34. The control circuit unit 18 also has the redundant system, and as can be seen from the drawings, control circuits configured by the microcomputers 32 and the peripheral circuits 33 such as transistors, which are arranged symmetrically with respect to each other, are provided. The microcomputers 32 and the peripheral circuits 33 are mounted on a surface (the other surface 34G shown in FIG. 10) at the power supply circuit unit 17 side of the glass epoxy circuit board 34.

This glass epoxy circuit board 34 is fixed to the bolt holes provided at tops of the circuit board fixing portions 26 with fixing bolts (not shown), as shown in FIG. 8, then a space in which the capacitors 29 and the coils 30 etc. of the power supply circuit unit 17 shown in FIG. 7 are arranged is provided between the glass epoxy circuit board 31 of the power supply circuit unit 17 and the glass epoxy circuit board 34 of the control circuit unit 18.

Further, the heat-releasing members (the heat-transmitting members) 38 are arranged on one surface (one surface 34F shown in FIG. 10) at the connector terminal assembly 13 side of the glass epoxy circuit board 34. Since the redundant system is employed in the present embodiment, two heat-releasing members 38 are provided for the redundant system. These detailed structures or configurations will be explained later using FIG. 10.

Next, FIG. 9 shows a state in which the connector terminal assembly 13 is mounted above or over the control circuit unit 18. As shown in FIG. 9, the connector terminal assembly 13 is mounted above or over the control circuit unit 18. The connector terminal assembly 13 is fixed to screw holes 26S provided at tops of board fixing portions 26A and 26B with fixing screws 36 so as to sandwich the control circuit unit 18 between the power supply circuit unit 17 and the connector terminal assembly 13. In this state, as shown in FIG. 3, the connector terminal assembly 13 is connected to the power conversion circuit unit 16, the power supply circuit unit 17 and the control circuit unit 18. Further, after fixing the connector terminal assembly 13, an opening end 37 of the metal cover 12 is connected to a stepped portion 35 of the motor housing 11, and fixed to the motor housing 11 by welding.

Next, a heat release structure of the present embodiment will be explained with reference to FIG. 10. In FIG. 10, penetration holes 39 are provided at a base body portion 13D that extends in a radial direction of the connector terminal assembly 13. These penetration holes 39 are holes into which the heat-releasing members 38 are inserted, and formed at arrangement positions of the heat-releasing members 38.

The heat-releasing member 38 inserted into the penetration hole 39 is made of good heat transfer material (or good thermal conductive material), e.g metal material such as copper and aluminum. However, the heat-releasing member 38 could be made of metal material except copper and aluminum or nonmetal material. In sum, any material can be used as long as the material has a function of efficiently transmitting and releasing heat.

The heat-releasing member 38 is shaped into a cylindrical column, and has a large diameter section 38L and a small diameter section 38S. The large diameter section 38L is formed into a shape that contacts the penetration hole 39 provided at the base body portion 13D of the connector terminal assembly 13. The small diameter section 38S is formed into a shape that contacts the one surface 34F of the glass epoxy circuit board 34 of the control circuit unit 18. Here, the shape of the heat-releasing member 38 could be a post or a column having no large diameter section 38L and no small diameter section 38S. Further, a cross section of the heat-releasing member 38 could be a polygon, not a circle.

Regarding the arrangement position at the glass epoxy circuit board 34 side of the small diameter section 38S of the heat-releasing member 38, the small diameter section 38S is arranged at a position at which the small diameter section 38S is projected onto a part or all of the peripheral circuit 33 placed on the surface 34G of the glass epoxy circuit board 34. That is, since the peripheral circuit 33 has a bipolar transistor etc., temperature in this region tends to be high. Therefore, to efficiently release or remove heat from the peripheral circuit 33 to the heat-releasing member 38, the small diameter section 38S of the heat-releasing member 38 is positioned close to the peripheral circuit 33, more specifically, close to the bipolar transistor.

It is noted that even if a project area of the small diameter section 38S of the heat-releasing member 38 does not overlap the peripheral circuit 33, as long as the heat release can be adequately performed, the small diameter section 38S is not necessarily arranged at the position at which the small diameter section 38S is projected onto a part or all of the peripheral circuit 33.

An adhesive 40B is applied between the small diameter section 38S of the heat-releasing member 38 and the one surface 34F of the glass epoxy circuit board 34. With this, the small diameter section 38S of the heat-releasing member 38 and the one surface 34F of the glass epoxy circuit board 34 are firmly fixed (bonded) together. If a relative movement between the small diameter section 38S of the heat-releasing member 38 and the one surface 34F of the glass epoxy circuit board 34 is allowed, there is a risk that the one surface 34F of the glass epoxy circuit board 34 will be damaged. However, when the small diameter section 38S of the heat-releasing member 38 and the one surface 34F of the glass epoxy circuit board 34 are fixed with the adhesive 40B like the present embodiment, the risk of the damage can be reduced.

Here, although heat conductivity of the adhesive is not so high in general, if ceramics having a high thermal conductivity, such as alumina, aluminium nitride, silicon carbide and graphite, are added as a filler to the adhesive then this adhesive having adhesiveness and heat transfer performance (thermal conductivity) is used, it is possible to radiate or release heat more efficiently.

Further, an adhesive 40B is applied between the large diameter section 38L of the heat-releasing member 38 and the base body portion 13D of the connector terminal assembly 13. With this, the large diameter section 38L of the heat-releasing member 38 and the base body portion 13D are firmly fixed (bonded) together, then the base body portion 13D and the glass epoxy circuit board 34 are firmly connected, by the heat-releasing member 38.

On the other hand, a metal cover 12 side of the large diameter section 38L of the heat-releasing member 38 is in a free state. Between the large diameter section 38L of the heat-releasing member 38 and a side surface wall 12U of the metal cover 12, a predetermined gap G is provided, and this gap G is filled with a good heat transfer liquid resin (or a good thermal conductive liquid resin), e.g. a heat transfer grease (also called a thermal conductive grease) 41. Therefore, heat from the heat-releasing member 38 can be efficiently released or transmitted to the side surface wall 12U of the metal cover 12 through the heat transfer grease 41.

Here, even if there is a deviation of size of components (variations in size of components) in the axial direction, since the metal cover 12 side of the large diameter section 38L of the heat-releasing member 38 is in the free state, the variations can be absorbed by the gap G. Further, even if a relative movement in a direction of the side surface wall 12U between the heat-releasing member 38 and the side surface wall 12U of the metal cover 12 occurs, since the gap G is provided, a load by this movement is not applied to the base body portion 13D of the connector terminal assembly 13 and the glass epoxy circuit board 34. This can therefore reduce the tendency for crack and damage to occur in adhesive regions of the heat-releasing member 38 with the base body portion 13D of the connector terminal assembly 13 and with the glass epoxy circuit board 34.

As explained above, according to the present embodiment, the power conversion circuit unit 16 is mounted on the protruding heat releasing portions 28 formed on the power-conversion-circuit heat releasing section 15A. Therefore, heat generated at the switching element of the power conversion circuit unit 16 can be efficiently transmitted to the protruding heat releasing portion 28. Further, heat transmitted to the protruding heat releasing portion 28 diffuses through the power-conversion-circuit heat releasing section 15A, and is further transmitted to the side peripheral surface portion 11A of the motor housing 11, then is released to the outside.

Likewise, the power supply circuit unit 17 is mounted on the power-supply-circuit heat releasing section 15B. The surface at the power-supply-circuit heat releasing section 15B side of the glass epoxy circuit board 31 on which the circuit elements of the power supply circuit unit 17 are mounted is fixed to the side end wall 15 so as to contact the power-supply-circuit heat releasing section 15B. It is therefore possible to efficiently transmit heat generated at the power supply circuit unit 17 to the power-supply-circuit heat releasing section 158. Heat transmitted to the power-supply-circuit heat releasing section 15B is further transmitted to and diffuses through the side peripheral surface portion 11A of the motor housing 11, then is released to the outside.

Furthermore, besides connecting the glass epoxy circuit board 34 of the control circuit unit 18 to the circuit board fixing portion 26, the one surface 34F of the glass epoxy circuit board 34 and the metal cover 12 covering the glass epoxy circuit board 34 are thermally connected through the heat-releasing member 38. With this configuration, it is possible to adequately release heat generated from the transistor of the control circuit unit 18, then an influence of heat on the electronic circuit element that is susceptible to heat can be suppressed.

As described above, in the present invention, the plurality of circuit boards are stacked at the side end wall, located an opposite side to the output shaft portion of the rotation shaft of the electric motor, of the motor housing. And, besides the mount fixing portion for at least the one circuit board, the heat-releasing member that thermally connects the one surface of the circuit board and the metal cover covering the circuit board is provided between the one surface of the circuit board and the metal cover.

According to this configuration, besides connecting the circuit board to the mount fixing portion, the one surface of the circuit board and the metal cover are thermally connected through the heat-releasing member. Hence, it is possible to adequately release heat generated from the transistor, then an influence of heat on the electronic circuit element that is susceptible to heat can be suppressed.

The present invention is not limited to the above embodiment, and includes all design modifications. The above embodiment is an embodiment that is explained in detail to easily understand the present invention, and the present invention is not necessarily limited to the embodiment having all elements or components described above. Further, a part of the configuration of the embodiment can be replaced with a configuration of other embodiments. Also, the configuration of other embodiments could be added to the configuration of the embodiment. Moreover, regarding a part of the configuration of the embodiment, the configuration of other embodiments could be added, removed and replaced.

As the electric driving device based on the above embodiment, for instance, the followings are raised.

That is, as one aspect of the present invention, an electric driving device comprises: a motor housing accommodating therein an electric motor that drives a mechanical control element; an electronic control unit provided at a side end wall side of the motor housing which is an opposite side to an output shaft portion of a rotation shaft of the electric motor and configured to drive the electric motor; and a metal cover fixed to the side end wall of the motor housing and covering the electronic control unit. And, the electronic control unit is configured by a plurality of stacked circuit boards, and besides a mount fixing portion for a specific circuit board that is at least one of the plurality of stacked circuit boards, a heat-releasing member that thermally connects one surface of the specific circuit board and the metal cover is provided between the one surface of the specific circuit board and the metal cover.

As a preferable aspect of the electric driving device, an electronic circuit element that generates heat is mounted on the other surface of the specific circuit board which is aback side of the one surface of the specific circuit board.

As another preferable aspect of the electric driving device, a circuit having a transistor is mounted on the other surface of the specific circuit board, and the heat-releasing member is arranged at a position that is close to the circuit having the transistor on the one surface of the specific circuit board.

As another preferable aspect of the electric driving device, the heat-releasing member and the one surface of the specific circuit board are bonded with an adhesive.

As another preferable aspect of the electric driving device, the adhesive is a thermal conductive adhesive to which a good thermal conductive filler is added.

As another preferable aspect of the electric driving device, a gap between the heat-releasing member and the metal cover is filled with a good thermal conductive liquid resin.

As another preferable aspect of the electric driving device, the good thermal conductive liquid resin is a thermal conductive grease.

As another preferable aspect of the electric driving device, a base body portion that forms a connector terminal is provided between the specific circuit board and the metal cover, and the heat-releasing member extends from the metal cover to the one surface of the specific circuit board through a penetration hole that is formed on the base body portion.

As another preferable aspect of the electric driving device, the heat-releasing member has a large diameter section that is engaged with the penetration hole formed on the base body portion, and the large diameter section and the base body portion are bonded with an adhesive.

As the electric power steering device based on the above embodiment, for instance, the followings are raised.

That is, as one aspect of the present invention, an electric power steering device comprises: an electric motor providing a steering assistive force to a steering shaft on the basis of an output from a torque sensor that detects a turning direction and a turning torque of the steering shaft; a motor housing accommodating therein the electric motor; an electronic control unit provided at a side end wall side of the motor housing which is an opposite side to an output shaft portion of a rotation shaft of the electric motor and configured to drive the electric motor; and a metal cover fixed to the side end wall of the motor housing and covering the electronic control unit. And, the electronic control unit is configured by a plurality of stacked circuit boards, and besides a mount fixing portion for a specific circuit board that is at least one of the plurality of stacked circuit boards, a heat-releasing member that thermally connects one surface of the specific circuit board and the metal cover is provided between the one surface of the specific circuit board and the metal cover.

As a preferable aspect of the electric power steering device, an electronic circuit element that generates heat is mounted on the other surface of the specific circuit board which is a back side of the one surface of the specific circuit board.

As another preferable aspect of the electric power steering device, a circuit having a transistor is mounted on the other surface of the specific circuit board, and the heat-releasing member is arranged at a position that is close to the circuit having the transistor on the one surface of the specific circuit board.

As another preferable aspect of the electric power steering device, the heat-releasing member and the one surface of the specific circuit board are bonded with an adhesive.

As another preferable aspect of the electric power steering device, the adhesive is a thermal conductive adhesive to which a good thermal conductive filler is added.

As another preferable aspect of the electric power steering device, a gap between the heat-releasing member and the metal cover is filled with a good thermal conductive liquid resin.

As another preferable aspect of the electric power steering device, the good thermal conductive liquid resin is a thermal conductive grease.

As another preferable aspect of the electric power steering device, a base body portion that forms a connector terminal is provided between the specific circuit board and the metal cover, and the heat-releasing member extends from the metal cover to the one surface of the specific circuit board through a penetration hole that is formed on the base body portion.

As another preferable aspect of the electric power steering device, the heat-releasing member has a large diameter section that is engaged with the penetration hole formed on the base body portion, and the large diameter section and the base body portion are bonded with an adhesive.

1. An electric driving device comprising:
a motor housing accommodating therein an electric motor that drives a mechanical control element;
an electronic control unit provided at a side end wall side of the motor housing which is an opposite side to an output shaft portion of a rotation shaft of the electric motor and configured to drive the electric motor; and
a metal cover fixed to the side end wall of the motor housing and covering the electronic control unit, and wherein
the electronic control unit is configured by a plurality of stacked circuit boards, and
besides amount fixing portion for a specific circuit board that is at least one of the plurality of stacked circuit boards, a heat-releasing member that thermally connects one surface of the specific circuit board and the metal cover is provided between the one surface of the specific circuit board and the metal cover.

2. The electric driving device as claimed in claim 1, wherein:
an electronic circuit element that generates heat is mounted on the other surface of the specific circuit board which is a back side of the one surface of the specific circuit board.

3. The electric driving device as claimed in claim 2, wherein:
a circuit having a transistor is mounted on the other surface of the specific circuit board, and
the heat-releasing member is arranged at a position that is close to the circuit having the transistor on the one surface of the specific circuit board.

4. The electric driving device as claimed in claim 3, wherein:
the heat-releasing member and the one surface of the specific circuit board are bonded with an adhesive.

5. The electric driving device as claimed in claim 4, wherein:
the adhesive is a thermal conductive adhesive to which a good thermal conductive filler is added.

6. The electric driving device as claimed in claim 3, wherein:
a gap between the heat-releasing member and the metal cover is filled with a good thermal conductive liquid resin.

7. The electric driving device as claimed in claim 6, wherein:
the good thermal conductive liquid res in is a thermal conductive grease.

8. The electric driving device as claimed in claim 3, wherein:
a base body portion that forms a connector terminal is provided between the specific circuit board and the metal cover, and
the heat-releasing member extends from the metal cover to the one surface of the specific circuit board through a penetration hole that is formed on the base body portion.

9. The electric driving device as claimed in claim 8, wherein:
the heat-releasing member has a large diameter section that is engaged with the penetration hole formed on the base body portion, and
the large diameter section and the base body portion are bonded with an adhesive.

10. An electric power steering device comprising:
an electric motor providing a steering assistive force to a steering shaft on the basis of an output from a torque sensor that detects a turning direction and a turning torque of the steering shaft;
a motor housing accommodating therein the electric motor;
an electronic control unit provided at a side end wall side of the motor housing which is an opposite side to an output shaft portion of a rotation shaft of the electric motor and configured to drive the electric motor; and
a metal cover fixed to the side end wall of the motor housing and covering the electronic control unit, and wherein
the electronic control unit is configured by a plurality of stacked circuit boards, and
besides amount fixing portion for a specific circuit board that is at least one of the plurality of stacked circuit boards, a heat-releasing member that thermally connects one surface of the specific circuit board and the metal cover is provided between the one surface of the specific circuit board and the metal cover.

11. The electric power steering device as claimed in claim 10, wherein:
an electronic circuit element that generates heat is mounted on the other surface of the specific circuit board which is a back side of the one surface of the specific circuit board.

12. The electric power steering device as claimed in claim 11, wherein:
a circuit having a transistor is mounted on the other surface of the specific circuit board, and
the heat-releasing member is arranged at a position that is close to the circuit having the transistor on the one surface of the specific circuit board.

13. The electric power steering device as claimed in claim 12, wherein:
the heat-releasing member and the one surface of the specific circuit board are bonded with an adhesive.

14. The electric power steering device as claimed in claim 13, wherein:
the adhesive is a thermal conductive adhesive to which a good thermal conductive filler is added.

15. The electric power steering device as claimed in claim 12, wherein:
a gap between the heat-releasing member and the metal cover is filled with a good thermal conductive liquid resin.

16. The electric power steering device as claimed in claim 15, wherein:
the good thermal conductive liquid resin is a thermal conductive grease.

17. The electric power steering device as claimed in claim 12, wherein:
a base body portion that forms a connector terminal is provided between the specific circuit board and the metal cover, and
the heat-releasing member extends from the metal cover to the one surface of the specific circuit board through a penetration hole that is formed on the base body portion.

18. The electric power steering device as claimed in claim 17, wherein:
the heat-releasing member has a large diameter section that is engaged with the penetration hole formed on the base body portion, and
the large diameter section and the base body portion are bonded with an adhesive.
